(19) United States
(12) Patent Application Publication
(10) Pub. No.: US 2026/0190751 A1
(43) Pub. Date: Jul. 2, 2026

(54) Display Apparatus

(71) Applicant: LG Display Co., Ltd., Seoul (KR)

(72) Inventor: YoungChul Jung, Gimcheon-si (KR)

(21) Appl. No.: 19/219,341

(22) Filed: May 27, 2025

(30) Foreign Application Priority Data
Dec. 30, 2024 (KR) 10-2024-0200111

(51) Int. Cl. H10K 59/80

(52) U.S. Cl. CPC H10K 59/80

(57) ABSTRACT

Provided is a display apparatus. The display apparatus comprises a display panel and a stiffener which supports the display panel on a rear surface of the display panel, wherein the stiffener includes a plurality of first stiffeners which extends in a first direction and a second stiffener which extends in a second direction intersecting with the first direction.

### CROSS-REFERENCE TO RELATED APPLICATION

This application claims the priority of Republic of Korea Patent Application No. 10-2024-0200111 filed on Dec. 30, 2024, which is hereby incorporated by reference in its entirety.

### FIELD

The present disclosure relates to a display apparatus, and more particularly, to a display apparatus in which a shock applied to a display panel is reduced.

### BACKGROUND

As display apparatus which are used for a monitor of a computer, a television, a cellular phone, or the like, there are an organic light emitting display (OLED) apparatus which is a self-emitting apparatus, a liquid crystal display (LCD) apparatus which requires a separate light source, and the like.

An applicable range of the display apparatus is diversified to personal digital assistants as well as monitors of computers and televisions and a display apparatus with a large display area and a reduced volume and weight is being studied.

In the meantime, studies on display apparatus which absorb shocks applied to various components of the display apparatus according to shocks from the outside, specifically, shocks applied to a display panel and suppress deformation of the display panel are being conducted.

### SUMMARY

An object to be achieved by the present disclosure is to provide a display apparatus in which a division structure is applied to a stiffener to reduce a shock applied to a display panel. Another object to be achieved by the present disclosure is to provide a display apparatus which concentrates a shock applied to a display panel on a connection unit of the stiffener to reduce a shock applied to the display panel.

Still another object to be achieved by the present disclosure is to provide a display apparatus which suppresses a shock applied to the display panel from being concentrated on a center portion of the display panel.

Objects of the present disclosure are not limited to the above-mentioned objects, and other objects, which are not mentioned above, can be clearly understood by those skilled in the art from the following descriptions.

According to an embodiment of the present disclosure, there is provided a display apparatus. The display apparatus comprises a display panel and a stiffener which supports the display panel on a rear surface of the display panel, wherein the stiffener includes a plurality of first stiffeners which extend in a first direction and a second stiffener which extends in a second direction intersecting with the first direction.

According to another embodiment of the present disclosure, there is provided a display apparatus. The display apparatus comprises a display panel and a stiffener which supports the display panel on a rear surface of the display panel, wherein the stiffener includes a plurality of first stiffeners including a plurality of concave patterns and a second stiffener which is disposed between the plurality of first stiffeners and includes a plurality of protruding patterns corresponding to the plurality of concave patterns.

Other detailed matters of the exemplary embodiments are included in the detailed description and the drawings.

According to the present disclosure, a stiffener which is formed of a rigid material is disposed on a rear surface of the display panel to protect the display panel.

According to the present disclosure, the stiffener is coupled using a plurality of concave patterns and a plurality of protruding patterns to improve a shock absorption rate applied to the display panel.

According to the present disclosure, the plurality of first stiffeners is disposed to be spaced apart from each other to easily absorb a shock applied to the display panel.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exploded perspective view of a display apparatus according to an exemplary embodiment of the present disclosure;

FIG. 2 is an exploded perspective view of a support layer of a display apparatus according to an exemplary embodiment of the present disclosure;

FIG. 3 is a plan view of a stiffener of a display apparatus according to an exemplary embodiment of the present disclosure;

FIGS. 4A to 4D are views for explaining a stress simulation result of a stiffener of a display apparatus according to an exemplary embodiment of the present disclosure; and

FIGS. 5A to 5D are views for explaining a strain simulation result of a stiffener of a display apparatus according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” other element or layer, another element or layer may be disposed directly on the other element or layer or interposed therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Further, spatially relative terms, such as “beneath,” “below,” “bottom,” “above,” “upper,” “top,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display apparatus according to exemplary embodiments of the present disclosure will be described in detail with reference to accompanying drawings.

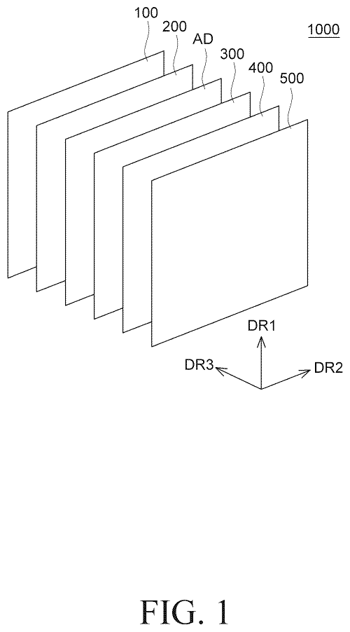

FIG. 1 is an exploded perspective view of a display apparatus according to an exemplary embodiment of the present disclosure.

Referring to FIG. 1, the display apparatus 1000 according to the exemplary embodiment of the present disclosure includes a cover window 100, a touch glass 200, an adhesive layer AD, a polarization layer 300, a display panel 400, and a support layer 500. It is noted that a first direction DR1, a second direction DR2, and a third direction DR3 orthogonal to each other are shown in FIG. 1. In an embodiment, the cover window 100, the touch glass 200, the adhesive layer AD, the polarization layer 300, the display panel 400, and the support layer 500 may be sequentially laminated in the third direction DR3, as shown on FIG. 1.

The cover window 100 is disposed above the display apparatus 1000. The cover window 100 is disposed so as to correspond to the display panel 400 to protect the display panel 400 from the shocks, the moisture, and heat from the outside.

The touch glass 200 is disposed on the rear surface of the cover window 100. The touch glass 200 converts a touch position which is directly touched by a user's hand or an object into an electrical signal and an instruction selected in the touch position may be input as an input signal.

The touch glass 200 may include a touch screen panel. A mutual-capacitance type in which a plurality of driving electrodes and a plurality of sensing electrodes intersect may be applied to the touch screen panel, but the touch screen panel is not limited thereto and may be implemented in various ways, such as a self-capacitance type.

The adhesive layer AD which fixes the touch glass 200 and the polarization layer 300 is disposed on a rear surface of the touch glass 200 and is between the touch glass 200 and the polarization layer 300. The adhesive layer AD may be formed as an optically clear adhesive (OCA) which minimizes foreign materials or bubbles generated between the touch glass 200 and the polarization layer 300. However, it is not limited thereto, and the adhesive layer AD may be omitted depending on an embodiment of the display apparatus 1000.

The polarization layer 300 may be disposed on rear surfaces of the touch glass 200 by the adhesive layer AD. The polarization layer 300 selectively transmits light to reduce reflection of external light which is incident onto the display panel 400 to suppress the degradation of visibility of the display apparatus 1000 due to the light reflection. However, it is not limited thereto and the polarization layer 300 may be omitted depending on an embodiment of the display apparatus 1000.

The display panel 400 is disposed on a rear surface of the polarization layer 300. The display panel 400 is a panel for displaying images to a user. In the display panel 400, a light emitting diode which displays images, a driving element which drives the light emitting diode, and wiring lines which transmit various signals to the light emitting diode and the driving element may be disposed.

The light emitting diode may be defined in different manners depending on the type of the display panel 400. For example, if the display panel 400 is an organic light emitting display panel, the light emitting diode may be an organic light emitting diode which includes an anode, an organic emission layer, and a cathode. Hereinafter, even though the display panel 400 is assumed as an organic light emitting display panel, the display panel 400 is not limited to the organic light emitting display panel. For example, the display panel 400 may also be a liquid crystal display panel.

In the meantime, even though it is not illustrated in the drawing, a plurality of circuits which drives the light emitting diode may be disposed on the display panel 400. For example, the plurality of flexible films and printed circuit boards may supply signals, such as a power voltage or a data voltage, to the light emitting diode of the display panel 400. The plurality of flexible films may be disposed along the second direction DR2 on one side of the display panel 400, but is not limited thereto.

The support layer 500 is disposed on the rear surface of the display panel 400. The support layer 500 not only supports the display panel 400, but also protects the display panel 400 from moisture, heat, and shocks from the outside. The support layer 500 may be disposed to have a shape corresponding to the display panel 400.

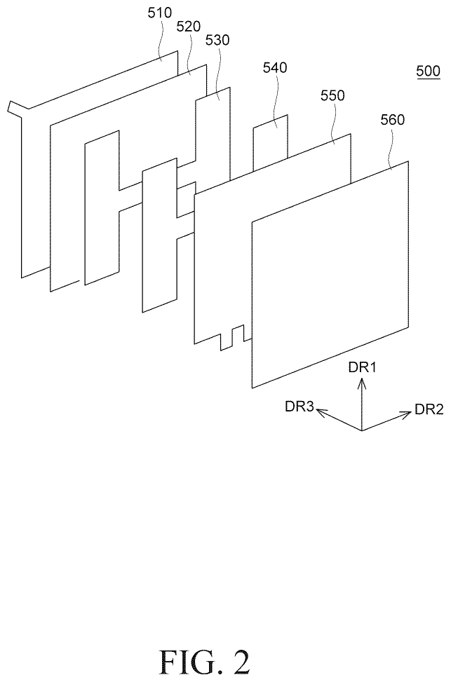

Hereinafter, the support layer 500 will be described in detail with reference to FIG. 2.

FIG. 2 is an exploded perspective view of a support layer of a display apparatus according to an exemplary embodiment of the present disclosure.

Referring to FIG. 2, the support layer 500 includes a first protection layer 510, a first heat dissipation layer 520, an adhesive pattern layer 530, a stiffener 540, a second heat dissipation layer 550, and a second protection layer 560. It is noted that a first direction DR1, a second direction DR2 and a third direction DR3 orthogonal to each other are also shown in FIG. 2. In an embodiment, a first protection layer 510, a first heat dissipation layer 520, an adhesive pattern layer 530, a stiffener 540, a second heat dissipation layer 550, and a second protection layer 560 may be sequentially laminated in the third direction DR3, as shown on FIG. 2.

The first protection layer 510 is disposed on a rear surface of the support layer 500. The first protection layer 510 is disposed on the rear surface of the display apparatus 1000 to protect the display apparatus 1000 and may be defined as a liner. The first protection layer 510 may be formed of polyethylene terephthalate (PET), but is not limited thereto.

The first heat dissipation layer 520 is disposed on a top surface of the first protection layer 510. The first heat dissipation layer 520 is disposed so as to correspond to the first protection layer 510 and may be attached on the entire top surface of the first protection layer 510. The first heat dissipation layer 520 may be formed of a metal material having a higher thermal conductivity. For example, the first heat dissipation layer 520 may be formed of a metal layer, such as copper. Therefore, the first heat dissipation layer 520 may perform a heat dissipation function and a ground function and a protecting function of the display panel 400.

The adhesive pattern layer 530 may be disposed on a top surface of the first heat dissipation layer 520. The adhesive pattern layer 530 may be disposed so as to correspond to the stiffener 540 and attach the stiffener 540 to the first heat dissipation layer 520. The adhesive pattern layer 530 may be formed of an optically clear adhesive (OCA), but is not limited thereto.

The stiffener 540 may be disposed on top surfaces of the first heat dissipation layer 520 by the adhesive pattern layer 530. The stiffener 540 may support the display panel 400 disposed above the stiffener 540. The stiffener 540 may be formed of a stainless steel (SUS), but is not limited thereto.

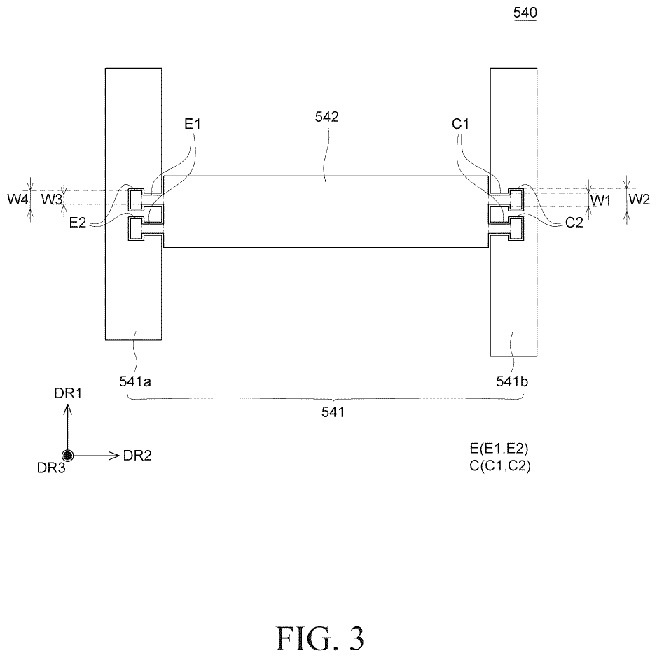

The stiffener 540 is disposed so as to correspond to a partial area of the display panel 400, but may not be disposed to correspond to the other partial area of the display panel 400. For example, the display apparatus 1000 may include a battery which is disposed so as to correspond to the other partial area of the display panel 400. Therefore, the stiffener 540 may be disposed in an area excluding the area where the battery is disposed. For example, the stiffener 540 may be disposed so as to overlap both ends of the display panel 400 in a second direction DR2, but may be disposed so as not to overlap the both ends of the display panel 400 in a first direction DR1, but is not limited thereto. The stiffener 540 will be described below in detail with reference to FIG. 3.

The second heat dissipation layer 550 is disposed on the top surface of the stiffener 540. The second heat dissipation layer 550 is disposed so as to correspond to the second protection layer 560 and may be attached on the entire rear surface of the second protection layer 560. The second heat dissipation layer 550 may be formed of a material having a higher thermal conductivity, such as graphite or carbon nanotube. For example, the second heat dissipation layer 550 may be formed by a graphite layer. Therefore, the second heat dissipation layer 550 may perform a heat dissipation function and a ground function, and a protecting function of the display panel 400.

The second protection layer 560 is disposed on a top surface of the second heat dissipation layer 550. The second protection layer 560 may protect the display panel 400 during the manufacturing process of the display apparatus 1000. Therefore, the second protection layer 560 may be referred to as a protection film. The second protection layer 560 may be formed of polyethylene terephthalate (PET), but is not limited thereto.

FIG. 3 is a plan view of a stiffener of a display apparatus according to an exemplary embodiment of the present disclosure.

Referring to FIG. 3, the stiffener 540 may include a plurality of first stiffeners 541 which extend in a first direction DR1 and a second stiffener 542 which extends in a second direction DR2.

Each of the plurality of first stiffeners 541 extends in the first direction DR1. For example, the plurality of first stiffeners 541 may be disposed along a side of the display panel 400 extending in the first direction DR1.

The plurality of first stiffeners 541 may include a plurality of concave patterns C which is concave in the second direction DR2. In an embodiment, each of the plurality of first stiffeners 541 may include the plurality of concave patterns C which are concave in the second direction DR2.

The plurality of concave patterns C may include a plurality of first concave patterns C1 in which a plurality of first protruding patterns E1 of the second stiffener 542 to be described below are disposed and a plurality of second concave patterns C2 in which a plurality of second protruding patterns E2 are disposed. For example, the plurality of second concave patterns C2 may be disposed to be closer to an outer periphery of the display panel 400 more than the plurality of first concave patterns C1. In an embodiment, each of the first concave patterns C1 is connected with the corresponding second concave pattern C2. At this time, in the first direction DR1, a width W1 of the first concave pattern C1 may be smaller than a width W2 of the second concave pattern C2.

The plurality of first stiffeners 541 may include a first sub stiffener 541a and a second sub stiffener 541b which are spaced apart from each other (i.e., two first stiffeners which are opposite to each other in the second direction) with the second stiffener 542 therebetween. For example, the first sub stiffener 541a and the second sub stiffener 541b may be disposed to be opposite to each other in the second direction DR2. At this time, each of the first sub stiffener 541a and the second sub stiffener 541b may be disposed such that a plurality of concave patterns C of the first sub stiffener 541a and a plurality of concave patterns C of the second sub stiffener 541b may be disposed to be opposite to each other.

The second stiffener 542 may be disposed between the first sub stiffener 541a and the second sub stiffener 541b. The second stiffener 542 may extend in the second direction DR2. For example, the second stiffener 542 may extend in the second direction DR2 and cross the center portion of the display panel 400.

In the meantime, the second stiffener 542 may be disposed to be spaced apart from the first sub stiffener 541a and the second sub stiffener 541b. For example, the second stiffener 542 may be disposed to be spaced apart from the first sub stiffener 541a and the second sub stiffener 541b with an interval of approximately 0.2 mm, but is not limited thereto.

The second stiffener 542 may include a plurality of protruding patterns E. For example, the second stiffener 542 may include a plurality of protruding patterns E which are disposed in each of the plurality of concave patterns C of the plurality of first stiffeners 541. In an embodiment, the second stiffener 542 may include a plurality of protruding patterns E disposed at both ends of the second stiffener opposite to each other along the second direction DR2, i.e., at least one pair of protruding patterns, but is not limited thereto.

The plurality of protruding patterns E may be disposed on one surface of the second stiffener 542 which is opposite to the first sub stiffener 541a and the other surface of the second stiffener 542 which is opposite to the second sub stiffener 541b.

Each of the plurality of protruding patterns E may include a first protruding pattern E1 disposed along the second direction DR2 and a second protruding pattern E2 connected to the first protruding pattern E1. For example, the second protruding pattern E2 may be disposed to be closer to an outer periphery of the display panel 400 more than the first protruding pattern E1.

At this time, the plurality of protruding patterns E of the second stiffener 542 may have a shape corresponding to the concave patterns C of the plurality of first stiffeners 541. For example, in the first direction DR1, a width W3 of the first protruding pattern E1 may be smaller than a width W4 of the second protruding pattern E2.

In the meantime, in the first direction DR1, the width W4 of the second protruding pattern E2 may be larger than the width W1 of the first concave pattern C1, but may be smaller than the width W2 of the second concave pattern C2. Accordingly, the second protruding pattern E2 disposed in the second concave pattern C2 may not be deviated to the first direction DR1 and/or the second direction DR2. Accordingly, the plurality of first stiffeners 541 and the second stiffener 542 may be coupled to each other through the plurality of concave patterns C and the plurality of protruding patterns E.

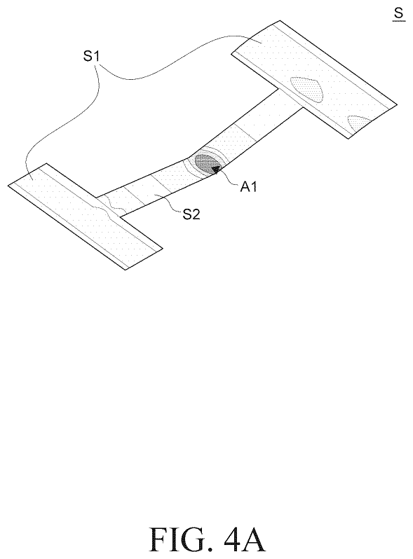

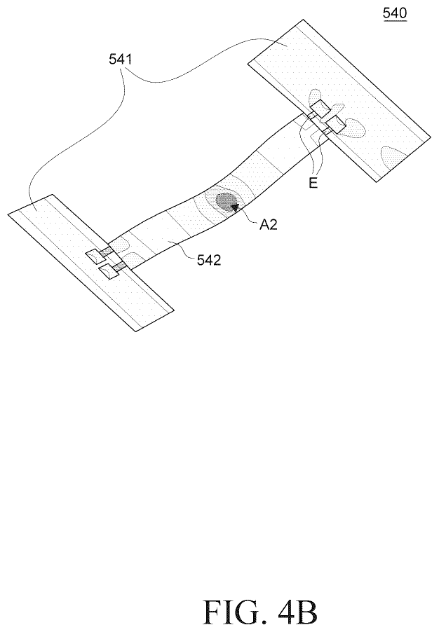

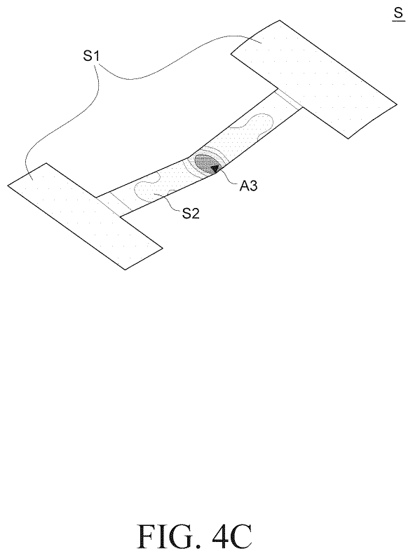

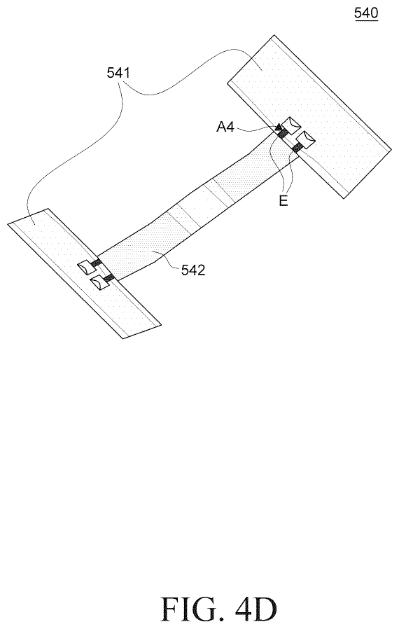

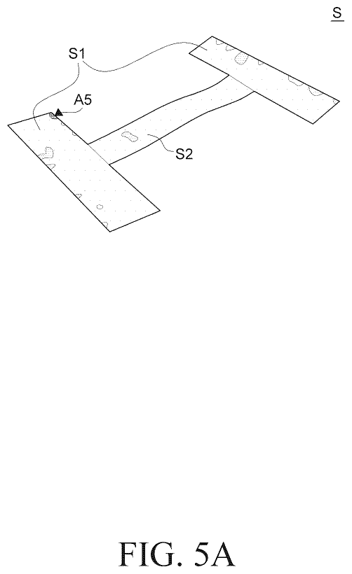

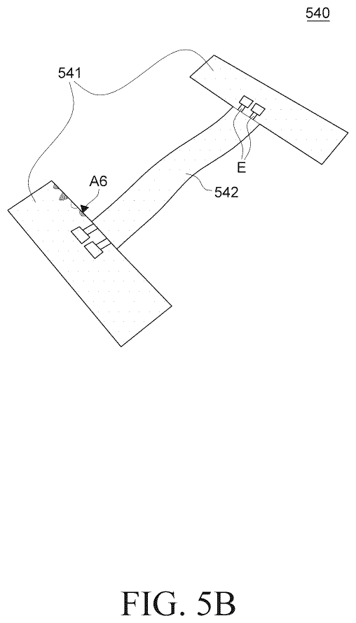

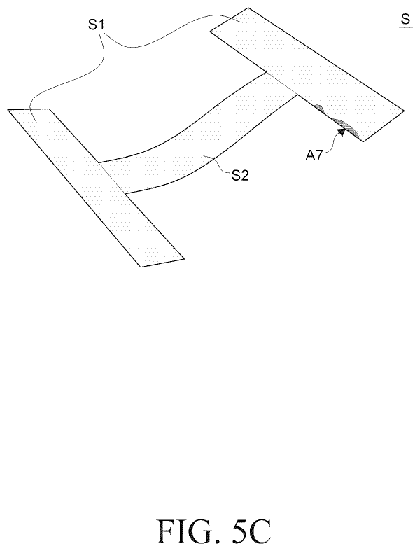

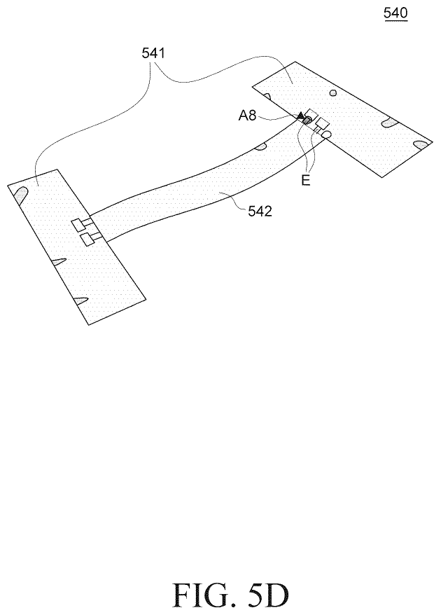

Hereinafter, the effect of the stiffener 540 of the display apparatus 1000 according to the exemplary embodiment of the present disclosure will be described with reference to FIGS. 4A to 5D.

FIGS. 4A to 4D are views for explaining a stress simulation result of a stiffener of a display apparatus according to an exemplary embodiment of the present disclosure. FIGS. 4A to 4D are a simulation result obtained by measuring stresses of a stiffener S of Comparative Embodiment and a stiffener 540 of Exemplary Embodiment when a ball is dropped in Comparative Embodiment and Exemplary Embodiment. The stiffener 540 of Exemplary Embodiment is the stiffener 540 of the display apparatus 1000 according to the exemplary embodiment of the present disclosure. The stiffener S of Comparative Embodiment is different from the stiffener 540 of the display apparatus 1000 according to the exemplary embodiment of the present disclosure only in that a plurality of concave patterns C is not disposed in the plurality of first stiffeners S1 and a plurality of protruding patterns E is not disposed in a second stiffener S2. FIG. 4A is a simulation result obtained by measuring a stress of a stiffener S of Comparative Embodiment when a ball is dropped in a center portion of the second stiffener S2 of Comparative Embodiment. FIG. 4B is a simulation result obtained by measuring a stress of a stiffener 540 of Exemplary Embodiment when a ball is dropped in a center portion of the second stiffener 542 of Exemplary Embodiment. FIG. 4C is a simulation result obtained by measuring a stress of a stiffener S of Comparative Embodiment when a ball is dropped in a boundary portion of the plurality of first stiffeners S1 and the second stiffener S2 of Comparative Embodiment. FIG. 4D is a simulation result obtained by measuring a stress of a stiffener 540 of Exemplary Embodiment when a ball is dropped in a boundary portion of the plurality of first stiffeners 541 and the second stiffener 542 of Exemplary Embodiment. In FIGS. 4A to 4D, it means that the higher the density of points represented in an area, the higher the stress.

A maximum stress of the stiffener S of Comparative Embodiment and a maximum stress of the stiffener 540 of Exemplary Embodiment illustrated in FIGS. 4A to 4B are represented in the following Table 1.

TABLE 1

| | Comparative | Exemplary |
|---|---|---|
| | Embodiment | Embodiment |
| Maximum Stress | 40.55 MPa | 40.78 MPa |

Referring to FIG. 4A, as a result of measuring a stress of the stiffener S of Comparative Embodiment, it is confirmed that an area A1 in which a maximum stress is obtained is located in the center portion of the second stiffener S2. Further, referring to Table 1, it is confirmed that a maximum stress of the stiffener S of Comparative Embodiment in the area A1 in which the maximum stress is obtained is approximately 40.55 MPa.

Next, referring to FIG. 4B, as a result of measuring a stress of the stiffener 540 of Exemplary Embodiment, it is confirmed that an area A2 in which a maximum stress is obtained is located in the center portion of the second stiffener 542. Further, referring to Table 1, it is confirmed that a maximum stress of the stiffener 540 of Exemplary Embodiment in the area A2 in which the maximum stress is obtained is approximately 40.78 MPa.

Therefore, it is confirmed that the maximum stress generated in the stiffener 540 of Exemplary Embodiment is larger than the maximum stress generated in the stiffener S of Comparative Embodiment. At this time, the stress in FIGS. 4A and 4B refers to a stress which is applied to the stiffener, among shocks applied to the display apparatus, so that it means that the stiffener 540 of Exemplary Embodiment absorbs more shocks than the stiffener S of Comparative Embodiment. Accordingly, it means that when the same shock is applied to the stiffener S of Comparative Embodiment and the stiffener 540 of Exemplary Embodiment, the stiffener 540 of Exemplary Embodiment absorbs more shocks applied to the display panel than the stiffener S of Comparative Embodiment.

Next, a maximum stress of the stiffener S of Comparative Embodiment and a maximum stress of the stiffener 540 of Exemplary Embodiment in FIGS. 4C and 4D are represented in the following Table 2.

TABLE 2

| | Comparative | Exemplary |
|---|---|---|
| | Embodiment | Embodiment |
| Maximum Stress | 25.49 MPa | 29.40 MPa |

Referring to FIG. 4C, as a result of measuring a stress of the stiffener S of Comparative Embodiment, it is confirmed that an area A3 in which a maximum stress is obtained is located in the center portion of the second stiffener S2. Further, referring to Table 2, it is confirmed that a maximum stress of the stiffener S of Comparative Embodiment in the area A3 in which the maximum stress is obtained is approximately 25.49 MPa.

Next, referring to FIG. 4D, as a result of measuring a stress of the stiffener 540 of Exemplary Embodiment, it is confirmed that the area A4 in which a maximum stress is obtained is located in the protruding pattern E of the second stiffener 542. Further, referring to Table 2, it is confirmed that a maximum stress of the stiffener 540 of Exemplary Embodiment in the area A4 in which the maximum stress is obtained is approximately 29.40 MPa.

Therefore, it is confirmed that the maximum stress generated in the stiffener 540 of Exemplary Embodiment is larger than the maximum stress generated in the stiffener S of Comparative Embodiment. At this time, the stress in FIGS. 4C and 4D refers to a stress which is applied to the stiffener, among shocks applied to the display apparatus so that it means that the stiffener 540 of Exemplary Embodiment absorbs more shocks than the stiffener S of Comparative Embodiment. Accordingly, it means that when the same shock is applied to the stiffener S of Comparative Embodiment and the stiffener 540 of Exemplary Embodiment, the stiffener 540 of Exemplary Embodiment absorbs more shock applied to the display panel than the stiffener S of Comparative Embodiment.

FIGS. 5A to 5D are views for explaining a strain simulation result of a stiffener of a display apparatus according to an exemplary embodiment of the present disclosure. FIGS. 5A to 5D are a simulation result obtained by measuring strains of a stiffener S of Comparative Embodiment and a stiffener 540 of Exemplary Embodiment when a ball is dropped in Comparative Embodiment and Exemplary Embodiment. The stiffener 540 of Exemplary Embodiment is the stiffener 540 of the display apparatus 1000 according to the exemplary embodiment of the present disclosure. The stiffener S of Comparative Embodiment is different from the stiffener 540 of the display apparatus 1000 according to the exemplary embodiment of the present disclosure only in that a plurality of concave patterns C is not disposed in the plurality of first stiffeners S1 and a plurality of protruding patterns E is not disposed in a second stiffener S2. FIG. 5A is a simulation result obtained by measuring a strain of a stiffener S of Comparative Embodiment when a ball is dropped in a center portion of the second stiffener S2 of Comparative Embodiment. FIG. 5B is a simulation result obtained by measuring a strain of a stiffener 540 of Exemplary Embodiment when a ball is dropped in a center portion of the second stiffener 542 of Exemplary Embodiment. FIG. 5C is a simulation result obtained by measuring a strain of a stiffener S of Comparative Embodiment when a ball is dropped in a boundary portion of the plurality of first stiffeners S1 and the second stiffener S2 of Comparative Embodiment. FIG. 5D is a simulation result obtained by measuring a strain of a stiffener 540 of Exemplary Embodiment when a ball is dropped in a boundary portion of the plurality of first stiffeners 541 and the second stiffener 542 of Exemplary Embodiment. In FIGS. 5A to 5D, it means that the higher the density of points represented in an area, the higher the strain.

A maximum strain of the stiffener S of Comparative Embodiment and a maximum strain of the stiffener 540 of Exemplary Embodiment in FIGS. 5A and 5B are represented in the following Table 3.

TABLE 3

| | Comparative | Exemplary |
|---|---|---|
| | Embodiment | Embodiment |
| Maximum Strain | 2.547e−03 | 1.570e−03 |

Referring to FIG. 5A, as a result of measuring a strain of the stiffener S of Comparative Embodiment, it is confirmed that an area A5 in which a maximum strain is obtained is located in an edge of the first stiffener S1. Further, referring to Table 3, it is confirmed that a maximum strain of the stiffener S of Comparative Embodiment in the area A5 in which the maximum strain is obtained is approximately 2.547e-03.

Next, referring to FIG. 5B, as a result of measuring a strain of the stiffener 540 of Exemplary Embodiment, it is confirmed that an area A6 in which a maximum strain is obtained is located in the edge of the first stiffener 541. Further, referring to Table 3, it is confirmed that a maximum strain of the stiffener 540 of Exemplary Embodiment in the area A6 in which the maximum strain is obtained is approximately 1.570e-03.

Therefore, it is confirmed that in the stiffener 540 of Exemplary Embodiment, the strain is smaller than that of the stiffener S of Comparative Embodiment. Accordingly, it means that when the same shock is applied to the stiffener S of Comparative Embodiment and the stiffener 540 of Exemplary Embodiment, the stiffener 540 of Exemplary Embodiment reduces the deformation of the display panel more than the stiffener S of Comparative Embodiment.

Next, a maximum strain of the stiffener S of Comparative Embodiment and a maximum strain of the stiffener 540 of Exemplary Embodiment in FIGS. 5C to 5D are represented in the following Table 4.

TABLE 4

| | Comparative | Exemplary |
|---|---|---|
| | Embodiment | Embodiment |
| Maximum Strain | 1.245e−02 | 7.598e−04 |

Referring to FIG. 5C, as a result of measuring a strain of the stiffener S of Comparative Embodiment, it is confirmed that an area A7 in which a maximum strain is obtained is located in an edge of the first stiffener S1. Further, referring to Table 4, it is confirmed that a maximum strain of the stiffener S of Comparative Embodiment in the area A7 in which the maximum strain is obtained is approximately 1.245e-02.

Next, referring to FIG. 5D, as a result of measuring a strain of the stiffener 540 of Exemplary Embodiment, it is confirmed that an area A8 in which a maximum strain is obtained is located in the protruding pattern E of the second stiffener 542. Further, referring to Table 4, it is confirmed that a maximum strain of the stiffener 540 of Exemplary Embodiment in the area A8 in which the maximum stress is obtained is approximately 7.598e-04.

Therefore, it is confirmed that in the stiffener 540 of Exemplary Embodiment, the strain is smaller than that of the stiffener S of Comparative Embodiment. Accordingly, it means that when the same shock is applied to the stiffener S of Comparative Embodiment and the stiffener 540 of Exemplary Embodiment, the stiffener 540 of Exemplary Embodiment reduces the deformation of the display panel more than the stiffener S of Comparative Embodiment.

The display panel of the display apparatus includes a plurality of light emitting diodes and a plurality of driving elements for driving the plurality of light emitting diodes. However, when the shock is applied to the display apparatus so that the shock is concentrated on the display panel, dark spots that the light emitting diode disposed on the display panel does not emit light may be caused. Therefore, in order to suppress the dark spots of the display apparatus, the support layer which supports the display panel is disposed on the rear surface of the display panel to absorb the shocks applied to the display panel.

Therefore, in the display apparatus 1000 according to the exemplary embodiment of the present disclosure, a stiffener 540 which is spaced apart from each other is disposed on the support layer 500 disposed on the rear surface of the display panel 400 to absorb shocks applied to the display panel 400. For example, if a rigid material which supports the display panel on the rear surface of the display panel is integrally formed, the shock applied to the display apparatus may propagate to the entire surface of the rigid material which supports the rigid display panel. Therefore, in the display apparatus 1000 according to the exemplary embodiment of the present disclosure, a stiffener 540 which is spaced apart from each other is disposed on the support layer 500 to suppress broad propagation of the shock applied to the display apparatus 1000. Accordingly, when collision due to the dropping occurs in the display apparatus 1000, the shocks may not be transmitted between the stiffeners 540 which are spaced apart from each other so that the display apparatus 1000 may be robust against the shock.

Further, in the display apparatus 1000 according to the exemplary embodiment of the present disclosure, the adjacent first stiffeners 541 and second stiffener 542, included in the stiffener 540, have an interconnection structure. Therefore, the bonding strength of the stiffener 540 may be strengthened and the shock absorption rate of the stiffener 540 may be increased and the strain may be reduced. For example, the display apparatus 1000 according to the exemplary embodiment of the present disclosure includes a second stiffener 542 including a plurality of protruding patterns E and a plurality of first stiffeners 541 which the second stiffener 542 is disposed between and include a plurality of concave patterns C. At this time, the plurality of protruding patterns E of the second stiffener 542 is disposed in the plurality of concave patterns C of the plurality of first stiffeners 541 and the plurality of first stiffeners 541 and the second stiffener 542 may be bound to each other. Accordingly, as the bonding strength of the plurality of first stiffeners 541 and the second stiffener 542 is enhanced, the rigidity of the stiffener 540 may also be enhanced. Therefore, the stiffener 540 may easily absorb shocks applied to the display panel 400 and reduce a strain of the display panel 400.

The exemplary embodiments of the present disclosure can also be described as follows:

According to an embodiment of the present disclosure, there is provided a display apparatus. The display apparatus comprises a display panel and a stiffener which supports the display panel on a rear surface of the display panel, wherein the stiffener includes a plurality of first stiffeners which extend in a first direction and a second stiffener which extends in a second direction intersecting with the first direction.

Each of the plurality of first stiffeners may include a plurality of concave patterns which are concave in the second direction.

The plurality of first stiffeners may include two first stiffeners which are opposite to each other in the second direction, and a plurality of concave patterns of one of the two first stiffeners and a plurality of concave patterns of the other of the two first stiffeners are disposed to be opposite to each other.

The second stiffener which extends in the second direction is between the two first stiffeners, and wherein the second direction is orthogonal to the first direction.

The second stiffener may be disposed to be spaced apart from the two first stiffeners.

The second stiffener may include a plurality of protruding patterns disposed at both ends of the second stiffener opposite to each other along the second direction.

Each of the plurality of protruding patterns may be disposed in a corresponding one of the plurality of concave patterns.

Each of the plurality of protruding patterns may include a first protruding pattern disposed along the second direction and a second protruding pattern connected to the first protruding pattern and in the first direction, a width of the first protruding pattern may be smaller than a width of the second protruding pattern.

Each of the plurality of concave patterns may include a first concave pattern in which the first protruding pattern is disposed and a second concave pattern in which the second protruding pattern is disposed and in the first direction, a width of the first concave pattern may be smaller than a width of the second concave pattern.

The second protruding pattern may be disposed to be closer to an outer periphery of the display panel more than the first protruding pattern.

According to another aspect of the present disclosure, there is provided a display apparatus. The display apparatus comprises a display panel and a stiffener which supports the display panel on a rear surface of the display panel, wherein the stiffener includes a plurality of first stiffeners including a plurality of concave patterns and a second stiffener which is disposed between the plurality of first stiffeners and includes a plurality of protruding patterns corresponding to the plurality of concave patterns.

Each of the plurality of first stiffeners may include a plurality of concave patterns which is concave in a second direction.

The plurality of first stiffeners may extend in a first direction orthogonal to the second direction, and the plurality of first stiffeners and the second stiffener may be coupled to each other through the plurality of concave patterns and the plurality of protruding patterns.

The plurality of first stiffeners may include two first stiffeners which are opposite to each other in the second direction.

A plurality of concave patterns of one of the two first stiffeners and a plurality of concave patterns of the other of the two first stiffeners may be disposed to be opposite to each other.

The second stiffener may be disposed between the two first stiffeners.

The second stiffener may be disposed to be spaced apart from the two first stiffeners.

The plurality of protruding patterns of the second stiffener are disposed at both ends of the second stiffener opposite to each other along the second direction.

Each of the plurality of protruding patterns may be disposed in a corresponding one of the plurality of concave patterns.

Each of the plurality of protruding patterns may include a first protruding pattern and a second protruding pattern which has a width larger than a width of the first protruding pattern in the first direction, and each of the plurality of concave patterns includes a first concave pattern in which the first protruding pattern is disposed and a second concave pattern in which the second protruding pattern is disposed and has a width smaller than a width of the second concave pattern in the first direction.

In the first direction, the width of the second protruding pattern may be larger than the width of the first concave pattern and is smaller than the width of the second concave pattern.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the appended claims, and all the technical concepts in the equivalent scope thereof should be construed as falling within the protective scope of the present disclosure.

What is claimed is:

1. A display apparatus, comprising:
a display panel; and
a stiffener that supports the display panel on a rear surface of the display panel,
wherein the stiffener includes a plurality of first stiffeners that extend in a first direction and a second stiffener that extends in a second direction that intersects with the first direction.

2. The display apparatus according to claim 1, wherein each of the plurality of first stiffeners includes a plurality of concave patterns that are concave in the second direction.

3. The display apparatus according to claim 2, wherein the plurality of first stiffeners include two first stiffeners which are opposite to each other in the second direction and a plurality of concave patterns of one of the two first stiffeners and a plurality of concave patterns of another of the two first stiffeners are disposed to be opposite to each other.

4. The display apparatus according to claim 3, wherein the second stiffener that extends in the second direction is between the two first stiffeners and the second direction is orthogonal to the first direction.

5. The display apparatus according to claim 4, wherein the second stiffener is spaced apart from the two first stiffeners.

6. The display apparatus according to claim 2, wherein the second stiffener includes a plurality of protruding patterns at both ends of the second stiffener opposite to each other along the second direction.

7. The display apparatus according to claim 6, wherein each of the plurality of protruding patterns is disposed in a corresponding one of the plurality of concave patterns.

8. The display apparatus according to claim 7, wherein each of the plurality of protruding patterns includes a first protruding pattern disposed along the second direction and a second protruding pattern that is connected to the first protruding pattern and in the first direction, a width of the first protruding pattern is less than a width of the second protruding pattern.

9. The display apparatus according to claim 8, wherein each of the plurality of concave patterns includes a first concave pattern in which the first protruding pattern is disposed and a second concave pattern in which the second protruding pattern is disposed and in the first direction, a width of the first concave pattern is less than a width of the second concave pattern.

10. The display apparatus according to claim 8, wherein the second protruding pattern is closer to an outer periphery of the display panel than the first protruding pattern.

11. A display apparatus, comprising:
a display panel; and
a stiffener that supports the display panel on a rear surface of the display panel,
wherein the stiffener includes a plurality of first stiffeners including a plurality of concave patterns and a second stiffener that is disposed between the plurality of first stiffeners and includes a plurality of protruding patterns corresponding to the plurality of concave patterns.

12. The display apparatus according to claim 11, wherein each of the plurality of first stiffeners includes a plurality of concave patterns that are concave in a second direction.

13. The display apparatus according to claim 12, wherein the plurality of first stiffeners extend in a first direction that is orthogonal to the second direction, and the plurality of first stiffeners and the second stiffener are coupled to each other through the plurality of concave patterns and the plurality of protruding patterns.

14. The display apparatus according to claim 12, wherein the plurality of first stiffeners include two first stiffeners that are opposite to each other in the second direction.

15. The display apparatus according to claim 14, wherein a plurality of concave patterns of one of the two first stiffeners and a plurality of concave patterns of another of the two first stiffeners are disposed to be opposite to each other.

16. The display apparatus according to claim 15, wherein the second stiffener is between the two first stiffeners.

17. The display apparatus according to claim 16, wherein the second stiffener is spaced apart from the two first stiffeners.

18. The display apparatus according to claim 13, wherein the plurality of protruding patterns of the second stiffener are disposed at both ends of the second stiffener opposite to each other along the second direction.

19. The display apparatus according to claim 18, wherein each of the plurality of protruding patterns is disposed in a corresponding one of the plurality of concave patterns.

20. The display apparatus according to claim 19 wherein each of the plurality of protruding patterns includes a first protruding pattern and a second protruding pattern that has a width that is larger than a width of the first protruding pattern in the first direction, and each of the plurality of concave patterns includes a first concave pattern in which the first protruding pattern is disposed and a second concave pattern in which the second protruding pattern is disposed and has a width that is smaller than a width of the second concave pattern in the first direction.

21. The display apparatus according to claim 20, wherein in the first direction, the width of the second protruding pattern is larger than the width of the first concave pattern and is smaller than the width of the second concave pattern.
